(19) United States
(12) Patent Application Publication
(10) Pub. No.: US 2025/0194429 A1
(43) Pub. Date: Jun. 12, 2025

(54) RADIO FREQUENCY SIGNAL CORRELATOR UTILIZING PARAMETRIC PUMPING OF SPIN WAVES

(71) Applicant: Oregon State University, Corvallis, OR (US)

(72) Inventors: Pallavi DHAGAT, Corvallis, OR (US); Albrecht JANDER, Corvallis, OR (US); Ivan LISENKOV, Natick, MA (US)

(73) Assignee: Oregon State University, Corvallis, OR (US)

(21) Appl. No.: 18/844,373

(22) PCT Filed: Apr. 26, 2023
(86) PCT No.: PCT/US2023/020046

§ 371 Date: Sep. 5, 2024

Related U.S. Application Data
(60) Provisional application No. 63/334,895, filed on Apr. 26, 2022.

(51) Int. Cl. H10N 35/00; H01F 10/20; H04B 5/24; H04B 5/40; H10N 39/00

(52) U.S. Cl. CPC H10N 35/00; H01F 10/20; H04B 5/24; H04B 5/40; H10N 39/00

(57) ABSTRACT

Various embodiments of a magneto-acoustic spin-wave signal processing system are provided. In one embodiment, a system includes an acoustic wave transducer configured to produce surface acoustic waves in a plane of a magnetostrictive material, wherein the magnetostrictive material serves as a medium for spin waves traveling in the plane, and wherein the acoustic wave transducer is oriented such that the acoustic waves parametrically amplify the spin waves. In this way, signal processing systems achieve the benefits of both spin wave and acoustic wave devices, taking advantage of the low dispersion and high dynamic range of acoustic waves coupled with the tunability and nonlinear effects provided by spin waves.

### ACKNOWLEDGMENT OF GOVERNMENT SUPPORT

This invention was made with government support under Award No. HR0011-17-2-0005 awarded by U.S. Defense Advanced Research Projects Agency (DARPA) Signal Processing at RF (SPAR). The government has certain rights in the invention.

### BACKGROUND

Magneto-acoustic devices exploit the interaction between magnetic and acoustic properties to enable applications in wireless communication, sensing, and information processing. These devices leverage the magnetostrictive effect, where magnetic materials undergo deformation in response to magnetic fields or induce changes in magnetization when subjected to mechanical stress. By harnessing this coupling between magnetic and acoustic domains, magneto-acoustic devices offer unique capabilities and performance advantages in various applications, such as transducers, filters, sensors, and communication systems.

### SUMMARY

Current magneto-acoustic transducers, filters, sensors, and communication systems face issues related to efficiency, frequency selectivity, tunability, and miniaturization. For instance, some transducers may exhibit limited conversion efficiency or frequency response, while existing filters struggle with precise frequency control and adaptability. Additionally, magneto-acoustic sensors may encounter challenges in sensitivity, stability, or response time when detecting physical changes or external stimuli, such as pressure, temperature, or magnetic fields.

Various embodiments of a magneto-acoustic spin-wave signal processing system are provided that may address these issues by providing advantages in energy efficiency, miniaturization, and interference resistance. In one embodiment, a system comprises an acoustic wave transducer configured to produce surface acoustic waves in a plane of a magnetostrictive material, wherein the magnetostrictive material serves as a medium for spin waves traveling in the plane, and wherein the acoustic wave transducer is oriented such that the acoustic waves parametrically amplify the spin waves. In this way, signal processing systems achieve the benefits of both spin wave and acoustic wave devices, taking advantage of the low dispersion and high dynamic range of acoustic waves coupled with the tunability and nonlinear effects provided by spin waves.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

The foregoing and other objects, features, and advantages of the invention will become more apparent from the following detailed description, which proceeds with reference to the accompanying figures.

### BRIEF DESCRIPTION OF THE DRAWINGS

FIG. 1 is a block diagram illustrating an example magneto-acoustic spin-wave signal processing system.

FIG. 2 is a schematic diagram illustrating an example SAW-pumped spin wave amplifier or correlator.

FIG. 3 is a schematic diagram illustrating another example SAW-pumped spin wave amplifier or correlator.

FIG. 4 is a diagram illustrating a relationship of wave vectors in SAW-pumped magneto-acoustic signal processing systems.

FIG. 5 is a schematic diagram illustrating relative positioning for an example SAW-pumped spin wave amplifier.

FIG. 6 is a schematic diagram illustrating relative positioning for an example SAW-pumped spin wave correlator.

FIG. 7 is a schematic diagram illustrating relative positioning of spin wave transducers and an acoustic wave transducer for an example SAW-pumped spin-wave signal processing system.

FIG. 8 is diagram illustrating an example computer simulation of spin wave and acoustic wave interaction in a planar device.

FIG. 9 is a high-level flow chart illustrating an example method for magneto-acoustic spin-wave signal processing.

FIG. 10 shows a block diagram illustrating an example radiofrequency (RF) communications system including a magneto-acoustic correlator.

FIG. 11 is a block diagram illustrating an example computing environment in which the described innovations may be implemented.

### DETAILED DESCRIPTION

The following description relates to various embodiments for a magneto-acoustic spin-wave signal processing system. In particular, various embodiments of signal processing devices are provided that marry the benefits of spin wave and acoustic wave devices, taking advantage of the low dispersion and high dynamic range of acoustic waves coupled with the tunability and nonlinear effects provided by spin waves. The signal processing systems described herein employ the interactions between acoustic waves and spin waves in magnetostrictive materials. In such materials, strain (the propagating variable in acoustic waves) and magnetization (the propagating variable in spin waves) are coupled. The strength of this coupling depends on the material in which the waves are travelling and is measured by the magnetostriction coefficient, or the magneto-elastic constants.

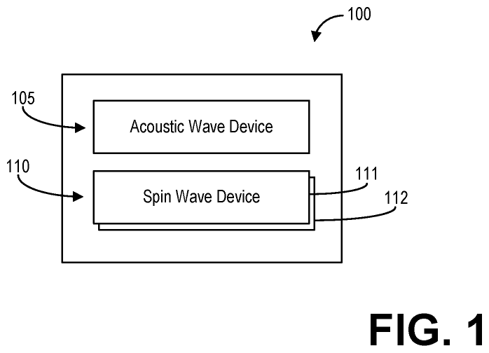

FIG. 1 shows a block diagram illustrating an example magneto-acoustic spin-wave signal processing system 100 according to an embodiment. The magneto-acoustic spin-wave signal processing system 100 comprises an acoustic wave device 105 and a plurality of spin wave devices 110.

The acoustic wave device 105 comprises an acoustic signal processing device configured to convert electronic signals to acoustic waves and acoustic waves to electronic signals. Acoustic signal processing devices—in which electronics signals are converted to acoustic waves, operated upon, and subsequently turned back into electronic signals—are widely used in radio-frequency (RF) and microwave communications equipment, including mobile phones. Converting signals into the acoustic domain for processing is advantageous since acoustic waves propagate several orders of magnitude more slowly compared to electromagnetic waves, so that, at a given frequency, the wavelengths are proportionately shorter (by up to five orders magnitude), enabling much smaller sized devices.

Acoustic wave devices such as acoustic wave device 105 fall into two main categories, surface acoustic wave (SAW) devices and bulk acoustic wave (BAW) devices. SAW devices make use of acoustic modes that are confined to and propagate along the surface of a solid. Surface acoustic waves are mechanical waves that propagate along the surface of a material, with the wave energy concentrated within a few wavelengths of the surface. In surface acoustic waves, the particles of the material exhibit both longitudinal and transverse displacements, while the amplitude of the wave decreases exponentially towards the material, resulting in most of the wave energy being confined to the surface. In contrast, BAW devices make use of waves that propagate into the bulk of the material. For example, bulk acoustic waves propagate through the bulk or volume of a material. To that end, bulk acoustic waves may be longitudinal waves, where the particle displacement is parallel to the direction of wave propagation, or transverse waves, where the particle displacement is perpendicular to the direction of wave propagation.

In a SAW device, the structures that convert electrical signals into surface acoustic waves, known as interdigitated transducers (IDTs), consist of two electrically isolated, thin-film, metal regions patterned into interleaved fingers on top of (or in some cases underneath) a piezoelectric material. When an alternating voltage is applied to the IDTs, the interaction of the electric field with the piezoelectric material results in a spatially and temporally periodic strain. If both the temporal as well as the spatial periodicity match a surface acoustic wave mode that can propagate on the surface of the device, then such a wave will be efficiently generated and propagate away from the IDT in the piezoelectric material. In the reciprocal process, when the wave reaches the second IDT, it is converted back to an electrical signal. This basic device structure is currently used to implement signal delays and frequency-selective filters with precisely designed filter shapes.

The transducers for BAW devices consist of two thin-film metal plates sandwiching a piezoelectric material. When excited with an alternating electric voltage, these transducers generate acoustic plane waves that propagate through the underlying material and reflect from the bottom surface. As in a guitar string, the structure resonates when the round-trip path length equals a multiple of the acoustic signal wavelength. Such BAW resonators are used to select a well-defined, narrow range of RF or microwave frequencies.

Key properties of acoustic wave devices such as the acoustic wave device 105 include low frequency dispersion, a large linear dynamic range, very low power losses and efficient transducers. The acoustic wave device 105 is described herein with regard to SAW devices, though it should be appreciated that the systems and methods provided herein may be implemented with one or more BAW devices or a combination of SAW and BAW devices in some examples.

The plurality of spin wave devices 110 comprises at least a first spin wave device 111. In some examples, the plurality of spin wave devices 110 further comprises a second spin wave device 112. In other examples, the plurality of spin wave devices 110 further comprises additional spin wave devices (not shown), such as a third spin wave device. Spin waves are propagating disturbances in the magnetization of an otherwise uniformly magnetized magnetic material. Similar to acoustic waves, spin waves also travel with velocities several orders of magnitude slower than electromagnetic waves. However, the velocity depends not only on the host material but also on the strength of an applied magnetic bias field and the frequency of the wave. This variability in velocity is both an opportunity for making tunable devices as well as a difficulty in the design of practical, manufacturable device implementations.

The spin wave devices 110 comprise spin wave transducers. Spin wave transducers comprise meandering conductors patterned onto the surface of a magnetic film such as yttrium-iron-garnet (YIG). The magnetic film comprises a magnetostrictive material. Other magnetic films may include ferromagnetic films including but not limited to magnetite, spinel ferrites, hexaferrites, manganese-zinc ferrite, lithium ferrite, and garnet-type ferrimagnets other than YIG such as gadolinium-gallium-garnet, terbium-gallium-garnet, and bismuth-iron-garnet. Alternating electric currents applied through these conductors produce spatially and temporally periodic magnetic fields which, similar to the SAW transducers, couple selectively to propagating spin wave modes in the magnetic film.

The spin waves propagate laterally from one transducer to the other, such as from the first spin wave device 111 to the second spin wave device 112, and thus the functions implemented are analogous to the SAW devices such as the acoustic wave device 105. In fact, similar methodologies are used to design the desired frequency filter shapes in both types of devices. Spin wave-based devices are currently not used commercially. Although spin waves can be used to implement linear devices such as filters, to date, this field has been dominated by acoustic wave devices which are easier to design and manufacture. Using spin waves, rather than acoustic waves, would be particularly advantageous for devices that implement non-linear signal processing functions such as modulation, correlation, and power limiting.

Key properties of spin waves devices include frequency or delay tunability, and nonlinear response. The power losses are generally higher than in acoustic devices, though there are indications that at frequencies beyond 5 GHZ, spin wave losses may be less than acoustic wave losses.

As one example of a magneto-acoustic spin-wave signal processing system 100, the surface wave device 105 may comprise a BAW device such that the signal processing system 100 comprises a BAW-pumped spin wave amplifier. A BAW-pumped spin wave amplifier combines a spin wave delay line with a BAW resonator. By application of an electrical signal to one of the spin wave transducers 110 (e.g., spin wave device 111), a spin wave is produced, which travels in the ferromagnetic layer to the other spin wave transducer (e.g., spin wave device 112), where the spin wave is converted back to an electrical signal. In the region between the spin wave transducers, the spin wave passes through a region of acoustic waves generated by the BAW resonator (e.g., acoustic wave device 105). If the frequency of the acoustic waves is near twice the frequency of the spin waves, the magneto-elastic interactions between the two waves can result in amplification of the spin waves by a non-linear effect known as parametric pumping. In addition to amplification of the forward-travelling spin wave, parametric pumping produces a second spin wave, known as an idler wave, which travels in the reverse direction back to the first spin wave transducer (e.g., spin wave device 111). The parametric pumping process works only under specific conditions relating the frequencies and wavelengths of the three waves. Based on conditions of energy conservation, the sum of the frequencies of the signal spin wave (fₛ) and idler spin wave (fᵢ) must equal the frequency of the acoustic pump (fₚ), such that fₚ=fₛ+fᵢ. Additionally, the process must conserve momentum carried by the waves. Since the standing acoustic wave in the BAW resonator has zero momentum, the added forward spin waves and the idler wave must have equal and opposite momentum (which is why the idler must travel in the opposite direction from the signal spin wave). The parametric pumping effect can be achieved by using yttrium-iron-garnet (YIG) as the ferromagnetic material supporting the spin waves and providing magneto-elastic coupling between the acoustic and spin waves.

The ability to amplify spin waves efficiently and locally in a ferromagnetic film, as proposed herein, may dramatically improve the performance of spin-wave-based signal processing devices, which are presently limited by the propagation loss of spin waves; even in the best of low spin-wave damping materials such as YIG, the spin-wave decay length does not exceed several millimeters. Amplifiers are also essential for the successful development of low-power magnonic logic circuits, as such amplifiers can provide signal restoration and fan-out between logic gates.

Prior approaches to spin wave amplification include parametric pumping by electromagnetic fields or voltage controlled magnetic anisotropy, as well as damping compensation by spin transfer torques. All of these electrical pumping techniques require a metal conductor to be routed over the spin wave waveguide. Paradoxically, introduction of conductors adjacent to the low-damping waveguide medium increases the spin wave decay rate and thus increases the passive insertion losses of the device. Acoustic pumping by remote transducers leaves the waveguide free of any conductive layers. Each of the existing methods of spin wave amplification has further limitations. In particular, methods of spin wave amplification by spin transfer torques or voltage-controlled magnetic anisotropy rely on interfacial spin-scattering, and are efficient only in ultra-thin (˜10 nm) magnetic films. Traditional parametric amplification by electromagnetic fields, which requires the ellipticity of the magnetization precession, cannot be realized in the geometry of perpendicular film magnetization relevant to modern-day magnonic circuits.

In addition to functioning as a signal amplifier, the magneto-acoustic spin-wave signal processing system 100 can also function as a signal correlator, also referred to as a convolver. If both the input spin wave signal and the acoustic pump signal are modulated, the generated idler wave will be modulated by the correlation of the two input modulations:

$$I ( t ) = {\int }_{0}^{{t}_{0}} S ( 2 τ - t ) P ( τ ) d τ \qquad ( 1 )$$

where S(t), P(t), and I(t) are the time-dependent modulation of the signal, pump, and idler, respectively, and to is the time that it takes for the spin wave to traverse the acoustic pump region.

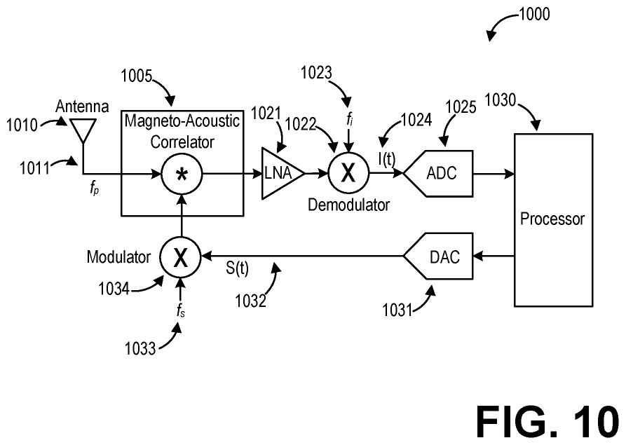

Correlators find application in RF communications systems employing code division multiple access (CDMA) schemes, in which signals are distinguished by their code modulation. A correlator can be used to selectively amplify only signals containing a specific code. A schematic of how such a system might be implemented is described further herein with regard to FIG. 10.

The range of frequencies over which the device operates is adjustable by the magnitude or direction of a magnetic field. Further, the range of frequencies over which the device operates is determined by the magnetic anisotropy of the magnetostrictive material. The range of frequencies over which the device operates is adjustable by a voltage-controlled magnetic anisotropy of the magnetostrictive material. In some examples, the acoustic wave transducer produces bulk acoustic waves propagating through the magnetostrictive material. In other examples, the acoustic transducer produces surface acoustic waves propagating on the surface of and producing strain in the magnetostrictive material. In yet other examples, the acoustic transducer produces Lamb waves or similar plate waves in the magnetostrictive material.

The magnetostrictive material comprises a ferrite material such as yttrium iron garnet (YIG) or another closely related magnetic garnet. In some examples, the magnetostrictive material comprises nickel (Ni), iron (Fe), or an alloy of nickel and iron. In other examples, the magnetostrictive material comprises CoFeB.

In some examples, the acoustic transducer comprises a bulk acoustic wave transducer producing standing acoustic waves in the substrate supporting the magnetostrictive material, the waves passing through the magnetostrictive material.

The acoustic wave transducer is oriented an angle such that the parametric interaction between the resulting acoustic wave and the spin wave results in a spin wave travelling at a third distinct angle to impinge on the output spin wave transducer. For example, the acoustic wave transducer is oriented at an angle such that the idler spin wave resulting from the parametric interaction between the surface acoustic wave and spin wave is a standing (non-propagating) spin wave. In some examples, the acoustic wave transducer is oriented at an angle such that the idler spin wave resulting from the parametric interaction between the surface acoustic wave and spin wave travels in the same direction as the input signal spin wave. In this way, the input spin wave transducer may also be configured to receive the idler spin wave. In some examples, the range of input frequencies for the input spin wave transducer and acoustic wave transducer are selected so that a third distinct frequency range is produce in the parametric interaction.

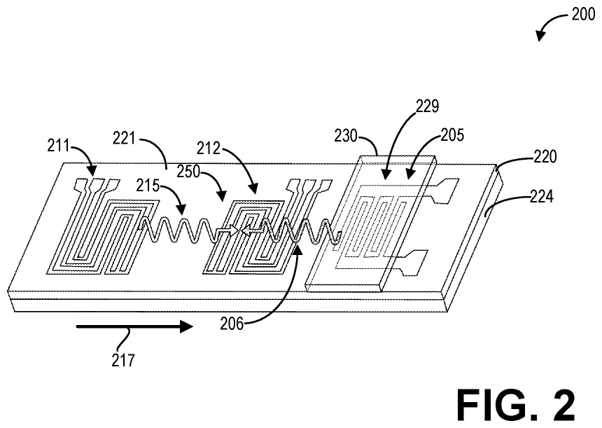

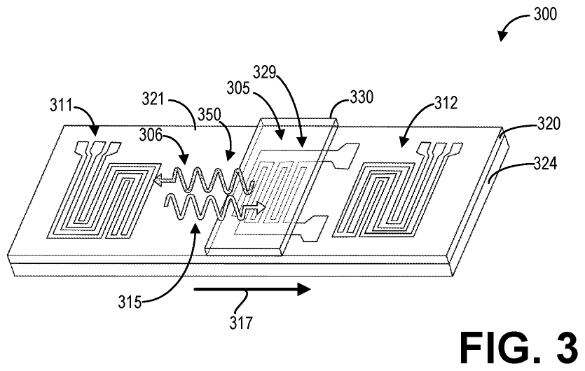

As an illustrative and non-limiting example, FIGS. 2 and 3 depict example magneto-acoustic spin-wave signal processing devices. For example, FIG. 2 is a schematic diagram illustrating an example magneto-acoustic spin-wave signal processing device 200 comprising a SAW-pumped spin wave amplifier or correlator that combines the spin wave delay line with a SAW delay line. The magneto-acoustic spin-wave signal processing device 200 comprises an acoustic wave device 205, a first spin wave device 211, and a second spin wave device 212 formed on the surface 221 of a ferromagnetic film 220 (e.g., YIG) covering a substrate 224 (e.g., alumina) of the device 200.

The acoustic wave device 205 is configured to generate acoustic waves such as a surface acoustic wave 206 that travels on the surface 221 of the ferromagnetic film 220. As depicted, the acoustic wave device 205 comprises an interdigitated transducer (IDT) 229 comprising a set of thin metal electrodes (e.g., formed from aluminum, gold, or another suitable metal material) patterned on the surface of a piezoelectric layer 230, where the electrodes are arranged in a comb-like or finger-like pattern with alternative electrodes connected to each other. When an electrical signal is applied to the IDT 229, the IDT 229 generates an electric field within the piezoelectric layer 230, causing mechanical deformation due to the piezoelectric effect. This deformation generates the surface acoustic wave 206 that propagates along the surface 221. The IDT 229 of the acoustic wave device 205 may be configured with particular electrode width, spacing, and number of finger pairs to control the properties of the generated SAWs, such as frequency, bandwidth, and amplitude.

The first spin wave device 211 is configured to generate spin waves such as spin wave 215 that travels on the surface 221 of the ferromagnetic film 220. The second spin wave device 212 is configured to receive the spin wave 215. As spin wave transducers comprise devices that convert electrical signals into spin waves or vice versa, the first spin wave device 211 thus comprises an input spin wave transducer while the second spin wave device 212 comprises an output spin wave transducer. A bias magnetic field 217 is applied in a direction from the first spin wave device 211 to the second spin wave device 212 to guide the spin wave 215 and control its propagation between the spin wave devices 211 and 212.

As depicted, both an acoustic wave 206 and a spin wave 215 travel in the ferromagnetic film 220 on the surface 221 of the magneto-acoustic spin-wave signal processing device 200. If the ferromagnetic film 220 is not piezoelectric, the IDT 229 for generating surface acoustic waves is covered with a piezoelectric layer 230, or alternatively the piezoelectric layer 230 is placed between the IDT 229 and the ferromagnetic film 220, to provide coupling between electrical and acoustic signals. The piezoelectric layer 230 may comprise zinc oxide (ZnO), as an illustrative and non-limiting example. Other example piezoelectric materials comprising the piezoelectric layer 230 include, but are not limited to, lead zirconate titanate (PZT), aluminum nitride (AlN), polyvinylidene fluoride (PVDF), barium titinate (BaTiO3), lithium niobate (LiNbO3), potassium sodium niobate (KNN), and the like. The choice of piezoelectric film may depend on desired performance, operating conditions, and the specific application.

In the central region 250 of the device 200, where the spin waves 215 and acoustic waves 206 travel together, the parametric interaction between acoustic waves 206 and spin waves 215 can lead to amplification of the spin waves 215 and generation of an idler spin wave (not depicted). Since acoustic waves typically propagate over longer distances than spin waves, it may be advantageous to place the acoustic transducer or acoustic wave device 205 outside of the spin wave transducers 211 and 212, as shown in FIG. 2. However, the acoustic transducer could also be placed between the spin wave transducers. As an illustrative and non-limiting example, FIG. 3 is a schematic diagram illustrating an example magneto-acoustic spin-wave signal processing system 300 comprising a SAW-pumped spin wave amplifier or correlator wherein an acoustic wave device 305 is positioned between a first spin wave device 311 and a second spin wave device 312 on the surface 321 of a ferromagnetic film 320 extending over a substrate 324. The acoustic wave device 305 comprises an IDT 329 and a piezoelectric layer 330, as depicted, configured to generate a surface acoustic wave 306 propagating along the surface 321 towards the first spin wave device 311 or input spin wave transducer. The first spin wave device 311 generates a spin wave 315 propagating along the surface 321 towards the second spin wave device 312, as guided by the ferromagnetic film 320 and the bias magnetic field 317. The acoustic wave 306 and the spin wave 315 thus parametrically interact in the central region 350 to amplify the spin wave 315 and generate an idler spin wave. As discussed further herein, the second spin wave device 312 may be positioned relative to this central region wherein the parametric interaction occurs to convert the amplified spin wave or the idler spin wave into an electric signal.

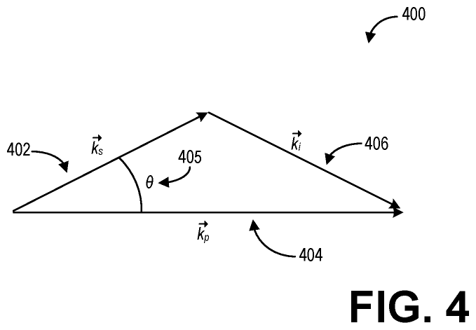

FIG. 4 shows a diagram illustrating an example vector relationship 400. For the parametric interaction between the acoustic wave and the spin wave to occur, the three waves (i.e., the acoustic wave, the spin wave, and the idler wave) must satisfy conditions dictated by energy and momentum conservation. These conditions are conventionally described by relationships between the frequencies and wave vectors of the three waves (the wave vector, k, points in the direction of wave propagation and has a magnitude of, k=2π/λ, where λ is the wavelength). The frequency of the pump wave (i.e., the acoustic wave that parametrically pumps the spin wave) must be equal to the sum of the signal wave (i.e., the input spin wave) and idler wave (i.e., the idler spin wave generated by the parametric interaction) frequencies:

$${f}_{p} = {f}_{s} + {f}_{i} , \qquad ( 2 )$$

and the pump wave vector 404 must be the vector sum of the signal wave vector 402 and the idler wave vector 406:

$${\vec{k}}_{p} = {\vec{k}}_{s} + {\vec{k}}_{i} . \qquad ( 3 )$$

The angle 405 between the propagating spin waves and acoustic waves (i.e., the angle between the signal wave vector 402 and the pump wave vector 404) defines the direction of the idler wave vector 406.

If the magnitude of the spin waves kₛ and kᵢ are similar, then the angle 405 (θ) between the signal spin wave and the acoustic wave must satisfy the relation:

$$\vert {k}_{p} \vert = 2 \vert {k}_{s} \vert cos θ . \qquad ( 4 )$$

Thus, according to this vector principle, the acoustic wave device 105 and the spin wave devices 110 of a magneto-acoustic spin-wave signal processing system 100 may be implemented in a planar arrangement as discussed with regard to FIGS. 2 and 3 with relative positioning to detect the amplified spin wave, the idler spin wave, or both the amplified spin wave and the idler spin wave.

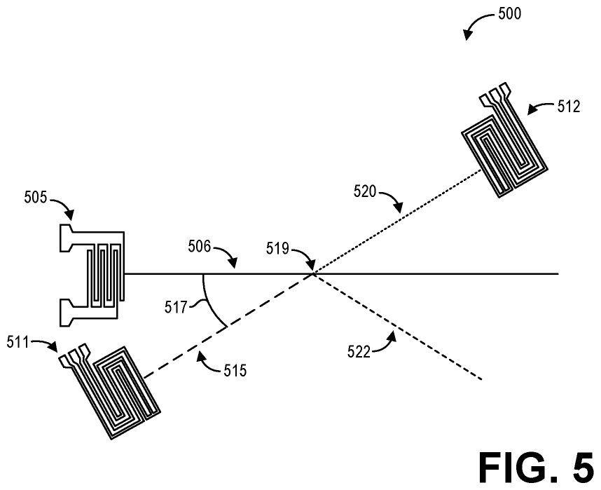

As an illustrative example, FIG. 5 is a schematic diagram illustrating relative positioning for an example SAW-pumped spin wave amplifier 500. Specifically, FIG. 5 illustrates a plan view of a layout for SAW and spin wave transducers that satisfy the wave vector relationship for parametric pumping. The output spin wave transducer is placed to capture the amplified signal spin wave. The IDTs of an acoustic wave device 505 are positioned relative to a first spin wave transducer 511 such that an angle 517 is formed between the acoustic wave 506 generated by the acoustic wave device 505 and the signal spin wave 515 generated by the first spin wave transducer 511. Due to parametric pumping in the region 519 where the acoustic wave 506 and the signal spin wave 515 interact, the signal spin wave 515 is amplified to produce the amplified spin wave 520 continuing in the same direction as the signal spin wave 515. Further, the angle 517 defines the propagation direction of the idler spin wave 522. The SAW-pumped spin wave amplifier 500 comprises an amplifier because the second spin wave transducer 512 is positioned to receive the amplified spin wave 520, as depicted.

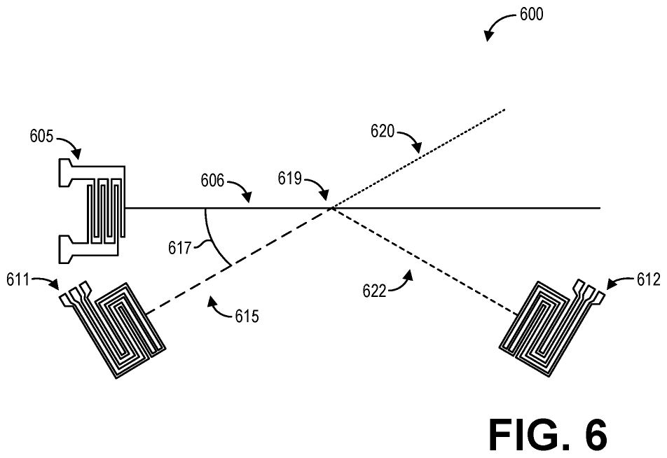

Similarly, FIG. 6 is a schematic diagram illustrating relative positioning for an example SAW-pumped spin wave correlator 600. Specifically, FIG. 6 illustrates a plan view of a layout for a SAW-pumped magneto-acoustic correlator with the output spin wave transducer placed to capture the idler spin wave. The IDTs of an acoustic wave device 605 are positioned relative to a first spin wave transducer 611 such that an angle 617 is formed between the acoustic wave 606 generated by the acoustic wave device 605 and the signal spin wave 615 generated by the first spin wave transducer 611. Due to parametric pumping in the region 619 where the acoustic wave 606 and the signal spin wave 615 interact, the signal spin wave 615 is amplified to produce the amplified spin wave 620 continuing in the same direction as the signal spin wave 615. Further, the angle 617 defines the propagation direction of the idler spin wave 622 generated by the parametric interaction. The SAW-pumped spin wave correlator 600 comprises a correlator because the second spin wave transducer 612 is positioned to receive the idler spin wave 622, as depicted.

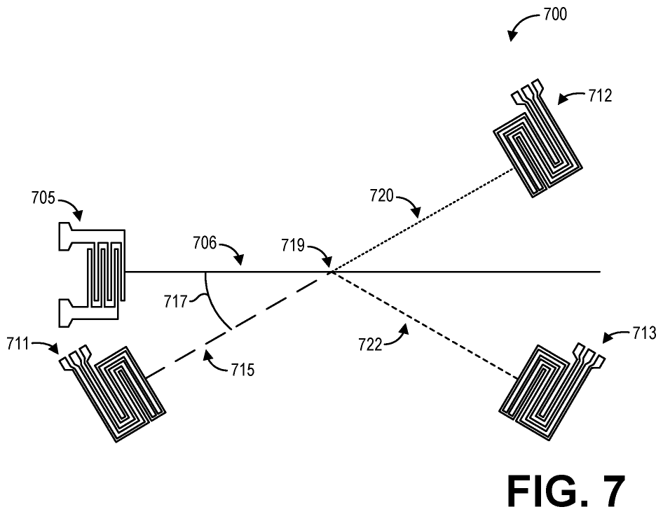

FIG. 7 is a schematic diagram illustrating relative positioning for an example SAW-pumped spin-wave signal processing system 700. Similar to the amplifier 500 and the correlator 600, the IDTs of an acoustic wave device 705 are positioned relative to a first spin wave transducer 711 such that an angle 717 is formed between the acoustic wave 706 generated by the acoustic wave device 705 and the signal spin wave 715 generated by the first spin wave transducer 711. Due to parametric pumping in the region 719 where the acoustic wave 706 and the signal spin wave 715 interact, the signal spin wave 715 is amplified to produce the amplified spin wave 720 continuing in the same direction as the signal spin wave 715. Further, the angle 717 defines the propagation direction of the idler spin wave 722 generated by the parametric interaction. The SAW-pumped spin-wave system 700 can function as both an amplifier and a correlator because a second spin wave transducer 712 is positioned to receive the amplified spin wave 720, while a third spin wave transducer 713 is positioned to receive the idler spin wave 722.

While acoustic waves are described generally herein, it should be appreciated that surface acoustic waves may be advantageous over bulk acoustic waves for parametric pumping in such devices for various reasons, such as: higher efficiency of parametric interactions; the ability to amplify forward volume spin waves which are the least dispersive modes of spin waves and can travel in any direction; and planar construction, which simplifies mass production.

A common problem in RF and microwave signal processing devices is unwanted feedthrough of the input signals to the output of the device. The above device architectures allow reduction of feedthrough by means of separating the input and output signals in frequency or angle.

Nondegenerate parametric pumping, in which the signal frequency is not exactly half of the pump frequency, can be used to separate the center frequencies of the input and output signals. As per equation (2), the sum of the signal and idler spin wave frequencies must equal the pump frequency. In degenerate parametric pumping, the signal and idler frequencies are equal and half of the pump frequency. In the nondegenerate case, the signal frequency may be displaced from half the pump frequency by Δf (higher or lower), in which case, to satisfy equation (2), the idler frequency will be displaced by −Δf (lower or higher) by which the input and output frequencies are separated by twice Δf. Frequency selective transducers or filters can then be used to prevent feedthrough of the signal to the output. Only nonlinear processes, such as parametric pumping, can introduce shifts in frequency. If the pump frequency is adjustable, different pump frequencies can be chosen dynamically to select different input frequency bands for amplification and correlation.

Both spin wave and acoustic wave transducers are sensitive to signals travelling only in a narrow range of angles. Therefore, per the geometries shown in FIGS. 5, 6, and 7, inadvertent coupling between input and output transducers can be reduced by the change in angle introduced in the parametric pumping process. In this way, only signals produced by the parametric interaction have the correct propagation angle to be captured by the output transducer.

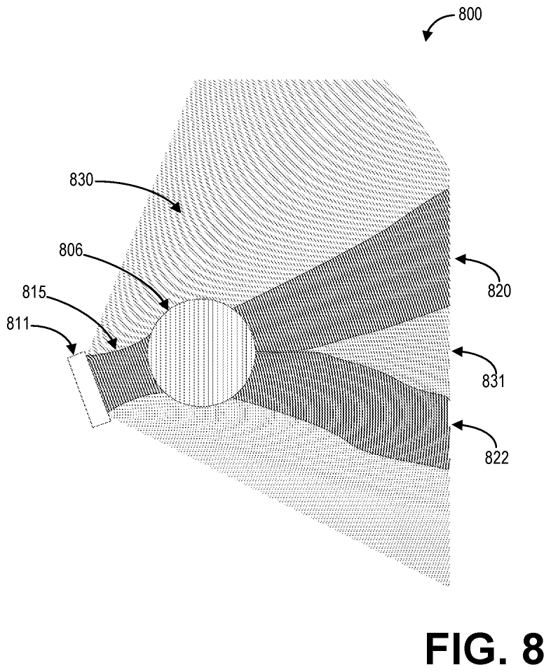

FIG. 8 shows a diagram illustrating an example computer simulation 800 of the interaction between spin waves and surface acoustic waves performed to demonstrate the parametric interaction of the waves in YIG and the validity of equations 2 through 4. As depicted, spin waves 815 emanating from a spin wave transducer 811 angled at twenty degrees to a simulated propagating SAW 806 are parametrically pumped to produce an idler spin wave 822 exiting the pump region at a distinct angle with respect to the signal spin wave 820. The magnitude of the spin waves in a region 830 away from the spin wave 815 is relatively negligible, and the simulation 800 indicates that the signal spin wave 820 is distinct from the idler spin wave 822, as depicted by the region 831 where the spin wave magnitude is relatively negligible.

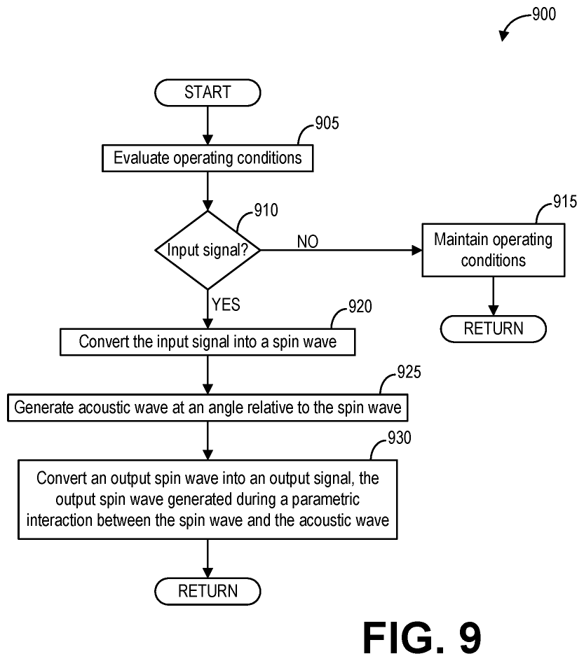

FIG. 9 shows a high-level flow chart illustrating an example method 900 for a magneto-acoustic spin-wave signal processing system. Method 900 may be implemented with the systems and components described hereinabove with regard to FIGS. 1-8, though it should be appreciated that method 900 may be implemented with other systems and components without departing from the scope of the present disclosure.

Method 900 begins at 905. At 905, method 900 evaluates operating conditions of the magneto-acoustic spin-wave signal processing system. At 910, method 900 determines whether an input signal is received. The input signal may comprise an input electrical or electromagnetic signal, for example. If an input signal is not received (“NO”), method 900 proceeds to 915, wherein method 900 maintains operating conditions. Method 900 then returns.

If an input signal is received (“YES”) at 910, then method 900 proceeds to 920. At 920, method 900 converts the input signal into a spin wave. The spin wave propagates along a planar surface. At 925, method 900 generates an acoustic wave at an angle relative to the spin wave. The acoustic wave propagates along the planar surface and parametrically interacts with the propagating spin wave at an interaction region.

At 930, method 900 converts an output spin wave into an output signal, wherein the output spin wave was generated during a parametric interaction between the spin wave and the acoustic wave. For example, the parametric interaction occurs at the interaction region. Depending on the arrangement of the spin wave and acoustic wave, as well as the magnitudes of the spin wave and acoustic wave, the output spin wave may comprise one or more of an amplified spin wave that is amplified by parametric pumping, an idler spin wave, or a combination of an amplified spin wave and an idler spin wave. Method 900 may convert the electrical signals to the spin waves with an input spin wave transducer, and convert the output spin waves to output electrical signals with an output spin wave transducer, wherein the output spin wave transducer is positioned relative to the input spin wave transducer to capture at least one of the spin waves parametrically amplified by the acoustic waves or the idler spin waves. Method 900 then returns.

FIG. 10 is a schematic block diagram illustrating an example RF communications system 1000 including a magneto-acoustic correlator 1005 configured to select specific code-modulated signals arriving at the antenna 1010. The magneto-acoustic correlator 1005 may comprise a SAW-pumped spin wave correlator as described hereinabove with regard to FIGS. 1-3, 6, and 7. Signals 1011 received by the antenna 1010 are provided to the magneto-acoustic correlator 1005. Only signals matching the code S (t) are passed on by the magneto-acoustic correlator 1005 to the low noise amplifier (LNA) 1021 for demodulation by a demodulator 1022. The idler frequency 1023 or fᵢ is provided to the demodulator 1022 to provide the demodulated signal 1024 or I(t). Further processing would typically be done by a digital processor 1030 after an analog-to-digital conversion (ADC) 1025 of the demodulated signal 1024. The processor 1030 can also produce the code signal S(t) using a digital-to-analog converter (DAC) 1031. The signal spin wave frequency 1033 or fₛ is input to the modulator 1034 with the code signal S(t) to provide input to the magneto-acoustic correlator 1005 for signal correlation.

Thus, various embodiments of a magneto-acoustic spin-wave signal processing system are provided. In some examples, a system comprises an acoustic wave transducer configured to produce acoustic waves in a magnetostrictive material serving as a medium for spin waves and oriented such that the acoustic waves parametrically amplify the spin waves. Such a system may be used to amplify spin wave signals in spin wave circuits (e.g., magnonic circuits). In other examples, a system comprises an input spin wave transducer, an output spin wave transducer, and an acoustic wave transducer arranged around a magnetostrictive material such that the acoustic waves produced by the acoustic transducer parametrically amplify spin waves as they travel within the magnetostrictive material from the input to the output transducer. Such a system may be used to amplify radio frequency electrical signals. In yet other examples, a system comprises an input spin wave transducer, an output spin wave transducer, and an acoustic wave transducer arranged around a magnetostrictive material such that the acoustic waves produced by the acoustic transducer parametrically interact with the spin waves produced by the input transducer as they travel within the magnetostrictive material and consequently generate an idler spin wave that travels to the output transducer. Such a system may be used to shift the center frequency of radio frequency electrical signals. In other examples, a system comprises an input spin wave transducer, an output spin wave transducer, and an acoustic wave transducer arranged around a magnetostrictive material such that the acoustic waves produced by the acoustic transducer parametrically interact with the spin waves produced by the input transducer as they travel within the magnetostrictive material and this parametric interaction extends over a specific region of space and specific duration in time. Such systems may be used to determine the time correlation or convolution of the modulations of two radio frequency electrical signals. Additionally or alternatively, such systems may be used to selectively block or amplify radio frequency signals depending on the code modulating the signals.

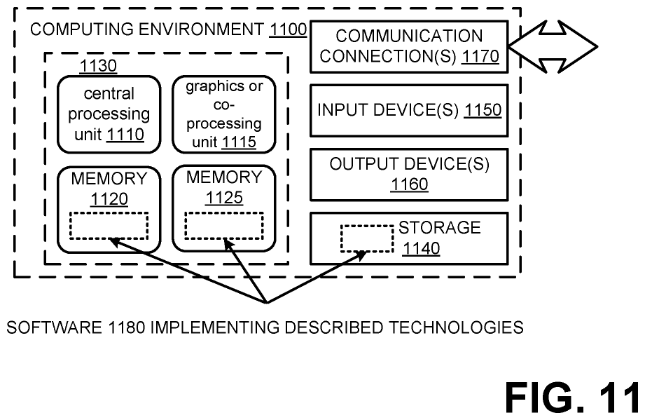

FIG. 11 depicts a generalized example of a suitable computing environment 1100 in which the described innovations may be implemented. The computing environment 1100 is not intended to suggest any limitation as to scope of use or functionality, as the innovations may be implemented in diverse general-purpose or special-purpose computing systems. For example, the computing environment 1100 can be any of a variety of computing devices (e.g., desktop computer, laptop computer, server computer, tablet computer, etc.).

With reference to FIG. 11, the computing environment 1100 includes one or more processing units 1110, 1115 and memory 1120, 1125. In FIG. 11, this basic configuration 1130 is included within a dashed line. The processing units 1110, 1115 execute computer-executable instructions. A processing unit can be a general-purpose central processing unit (CPU), processor in an application-specific integrated circuit (ASIC) or any other type of processor. In a multi-processing system, multiple processing units execute computer-executable instructions to increase processing power. For example, FIG. 11 shows a central processing unit 1110 as well as a graphics processing unit or co-processing unit 1115. The tangible memory 1120, 1125 may be volatile memory (e.g., registers, cache, RAM), non-volatile memory (e.g., ROM, EEPROM, flash memory, etc.), or some combination of the two, accessible by the processing unit(s). The memory 1120, 1125 stores software 1180 implementing one or more innovations described herein, in the form of computer-executable instructions suitable for execution by the processing unit(s).

A computing system may have additional features. For example, the computing environment 1100 includes storage 1140, one or more input devices 1150, one or more output devices 1160, and one or more communication connections 1170. An interconnection mechanism (not shown) such as a bus, controller, or network interconnects the components of the computing environment 1100. Typically, operating system software (not shown) provides an operating environment for other software executing in the computing environment 1100, and coordinates activities of the components of the computing environment 1100.

The tangible storage 1140 may be removable or non-removable, and includes magnetic disks, magnetic tapes or cassettes, CD-ROMs, DVDs, or any other medium which can be used to store information in a non-transitory way and which can be accessed within the computing environment 1100. The storage 1140 stores instructions for the software 1180 implementing one or more innovations described herein.

The input device(s) 1150 may be a touch input device such as a keyboard, mouse, pen, or trackball, a voice input device, a scanning device, or another device that provides input to the computing environment 1100. The output device(s) 1160 may be a display, printer, speaker, CD-writer, or another device that provides output from the computing environment 1100.

The communication connection(s) 1170 enable communication over a communication medium to another computing entity. The communication medium conveys information such as computer-executable instructions, audio or video input or output, or other data in a modulated data signal. A modulated data signal is a signal that has one or more of its characteristics set or changed in such a manner as to encode information in the signal. By way of example, and not limitation, communication media can use an electrical, optical, RF, or other carrier.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods.

Any of the disclosed methods can be implemented as computer-executable instructions stored on one or more computer-readable storage media (e.g., one or more optical media discs, volatile memory components (such as DRAM or SRAM), or non-volatile memory components (such as flash memory or hard drives)) and executed on a computer (e.g., any commercially available computer, including smart phones or other mobile devices that include computing hardware). The term computer-readable storage media does not include communication connections, such as signals and carrier waves. Any of the computer-executable instructions for implementing the disclosed techniques as well as any data created and used during implementation of the disclosed embodiments can be stored on one or more computer-readable storage media. The computer-executable instructions can be part of, for example, a dedicated software application or a software application that is accessed or downloaded via a web browser or other software application (such as a remote computing application). Such software can be executed, for example, on a single local computer (e.g., any suitable commercially available computer) or in a network environment (e.g., via the Internet, a wide-area network, a local-area network, a client-server network (such as a cloud computing network), or other such network) using one or more network computers.

For clarity, only certain selected aspects of the software-based implementations are described. Other details that are well known in the art are omitted. For example, it should be understood that the disclosed technology is not limited to any specific computer language or program. For instance, aspects of the disclosed technology can be implemented by software written in C++, Java, Perl, any other suitable programming language. Likewise, the disclosed technology is not limited to any particular computer or type of hardware. Certain details of suitable computers and hardware are well known and need not be set forth in detail in this disclosure.

It should also be well understood that any functionality described herein can be performed, at least in part, by one or more hardware logic components, instead of software. For example, and without limitation, illustrative types of hardware logic components that can be used include Field-programmable Gate Arrays (FPGAs), Program-specific Integrated Circuits (ASICs), Program-specific Standard Products (ASSPs), System-on-a-chip systems (SOCs), Complex Programmable Logic Devices (CPLDs), etc.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, software applications, cable (including fiber optic cable), magnetic communications, electromagnetic communications (including RF, microwave, and infrared communications), electronic communications, or other such communication means.

Thus, various embodiments of magneto-acoustic spin-wave signal processing systems are provided. In one embodiment, a system comprises an acoustic wave transducer configured to produce surface acoustic waves in a plane of a magnetostrictive material, wherein the magnetostrictive material serves as a medium for spin waves traveling in the plane, and wherein the acoustic wave transducer is oriented such that the acoustic waves parametrically amplify the spin waves.

In a first example of the system, the system further comprises an input spin wave transducer configured to generate the spin waves, and an output spin wave transducer configured to measure output spin waves, wherein the surface acoustic waves produced by the acoustic wave transducer parametrically amplify the spin waves as the spin waves travel within the magnetostrictive material from the input spin wave transducer. In a second example of the system optionally including the first example, the output spin waves comprise the spin waves parametrically amplified by the acoustic waves, and the output spin wave transducer measures the spin waves parametrically amplified by the acoustic waves. In a third example of the system optionally including one or more of the first and second examples, the input spin wave transducer converts electrical signals in a given frequency band to generate the spin waves, and the output spin wave transducer converts the parametrically amplified spin waves to amplified electrical signals in the given frequency band, wherein the given frequency band comprises one or more of a radio frequency band, a microwave frequency band, and a millimeter wave frequency band. In a fourth example of the system optionally including one or more of the first through third examples, the output spin waves comprise idler spin waves generated when the spin waves are parametrically amplified by the acoustic waves, and the output spin wave transducer measures the idler spin waves. In a fifth example of the system optionally including one or more of the first through fourth examples, the input spin wave transducer converts input electrical signals to generate the spin waves, and, to measure the idler spin waves, the output spin wave transducer converts the idler spin waves to output electrical signals with a center frequency shifted relative to a center frequency of the input electrical signals. In a sixth example of the system optionally including one or more of the first through fifth examples, the input spin wave transducer converts input electrical signals to generate the spin waves, and the output spin wave transducer converts the idler spin waves to output electrical signals usable for determining the time correlation or convolution of modulations of the input electrical signals. In a seventh example of the system optionally including one or more of the first through sixth examples, the acoustic wave transducer, the input spin wave transducer, and the output spin wave transducer are configured to selectively block or amplify electrical signals depending on a code modulating the electrical signals. In an eighth example of the system optionally including one or more of the first through seventh examples, the input spin wave transducer is positioned at an angle relative to the acoustic wave transducer, and the output spin wave transducer is positioned relative to the input spin wave transducer and the acoustic wave transducer based on the angle. In a ninth example of the system optionally including one or more of the first through eighth examples, the surface acoustic waves parametrically amplify the spin waves during a parametric interaction, and the parametric interaction extends over a specific region of space and specific duration in time. In a tenth example of the system optionally including one or more of the first through ninth examples, the acoustic wave transducer is configured to parametrically amplify the spin waves in one or more spin wave circuits. In an eleventh example of the system optionally including one or more of the first through tenth examples, a range of frequencies over which the device operates is adjustable by a magnetic field. In a twelfth example of the system optionally including one or more of the first through eleventh examples, the magnetostrictive material comprises a ferrite material. In a thirteenth example of the system optionally including one or more of the first through twelfth examples, the acoustic wave transducer is oriented at an angle such that an idler spin wave resulting from a parametric interaction between the acoustic waves and the spin waves is a standing, non-propagating spin wave. In a fourteenth example of the system optionally including one or more of the first through thirteenth examples, a range of input frequencies for the input spin wave transducer and the acoustic wave transducer are selected so that output spin waves in a third distinct frequency range are produced in a parametric interaction between the acoustic waves and the spin waves.

In another embodiment, a device comprises an acoustic transducer configured to produce surface acoustic waves in a plane of a magnetostrictive material, and at least one spin wave transducer configured to produce spin waves, wherein the spin waves propagate in the plane of the magnetostrictive material and parametrically interact with the surface acoustic waves.

In a first example of the device, the at least one spin wave transducer comprises an input spin wave transducer configured to generate the spin waves, and an output spin wave transducer configured to measure output spin waves, wherein the input spin wave transducer is positioned at an angle relative to the acoustic wave transducer, and wherein the output spin wave transducer is positioned relative to the acoustic wave transducer and the input spin wave transducer based on the angle to measure the output spin waves.

In yet another embodiment, a method comprises converting electrical signals to spin waves, wherein the spin waves propagate in a plane of a magnetostrictive material, generating acoustic waves in the plane of the magnetostrictive material at an angle relative to the spin waves, and converting output spin waves to output electrical signals, the output spin waves generated during a parametric interaction between the spin waves and the acoustic waves.

In a first example of the method, the output spin waves comprise one or more of the spin waves parametrically amplified by the acoustic waves or idler spin waves generated during the parametric interaction. In a second example of the method optionally including the first example, the method further comprises converting the electrical signals to the spin waves with an input spin wave transducer, and converting the output spin waves to output electrical signals with an output spin wave transducer, wherein the output spin wave transducer is positioned relative to the input spin wave transducer to capture at least one of the spin waves parametrically amplified by the acoustic waves or the idler spin waves.

The disclosed methods, apparatus, and systems should not be construed as limiting in any way. Instead, the present disclosure is directed toward all novel and nonobvious features and aspects of the various disclosed embodiments, alone and in various combinations and sub-combinations with one another. The disclosed methods, apparatus, and systems are not limited to any specific aspect or feature or combination thereof, nor do the disclosed embodiments require that any one or more specific advantages be present or problems be solved.

In view of the many possible embodiments to which the principles of the disclosed invention may be applied, it should be recognized that the illustrated embodiments are only examples of the invention and should not be taken as limiting the scope of the invention. We therefore claim as our invention all that comes within the scope of these claims.

1. A system, comprising:
an acoustic wave transducer configured to produce surface acoustic waves in a plane of a magnetostrictive material, wherein the magnetostrictive material serves as a medium for spin waves traveling in the plane, and wherein the acoustic wave transducer is oriented such that the acoustic waves parametrically amplify the spin waves.

2. The system of claim 1, further comprising:
an input spin wave transducer configured to generate the spin waves;
and an output spin wave transducer configured to measure output spin waves;
wherein the surface acoustic waves produced by the acoustic wave transducer parametrically amplify the spin waves as the spin waves travel within the magnetostrictive material from the input spin wave transducer.

3. The system of claim 2, wherein the output spin waves comprise the spin waves parametrically amplified by the acoustic waves, and wherein the output spin wave transducer measures the spin waves parametrically amplified by the acoustic waves.

4. The system of claim 3, wherein the input spin wave transducer converts electrical signals in a given frequency band to generate the spin waves, and wherein the output spin wave transducer converts the parametrically amplified spin waves to amplified electrical signals in the given frequency band, wherein the given frequency band comprises one or more of a radio frequency band, a microwave frequency band, and a millimeter wave frequency band.

5. The system of claim 2, wherein the output spin waves comprise idler spin waves generated when the spin waves are parametrically amplified by the acoustic waves, and wherein the output spin wave transducer measures the idler spin waves.

6. The system of claim 5, wherein the input spin wave transducer converts input electrical signals to generate the spin waves, and wherein, to measure the idler spin waves, the output spin wave transducer converts the idler spin waves to output electrical signals with a center frequency shifted relative to a center frequency of the input electrical signals.

7. The system of claim 5, wherein the input spin wave transducer converts input electrical signals to generate the spin waves, and wherein the output spin wave transducer converts the idler spin waves to output electrical signals usable for determining the time correlation or convolution of modulations of the input electrical signals.

8. The system of claim 5, wherein the acoustic wave transducer, the input spin wave transducer, and the output spin wave transducer are configured to selectively block or amplify electrical signals depending on a code modulating the electrical signals.

9. The system of claim 2, wherein the input spin wave transducer is positioned at an angle relative to the acoustic wave transducer, and wherein the output spin wave transducer is positioned relative to the input spin wave transducer and the acoustic wave transducer based on the angle.

10. The system of claim 2, wherein the surface acoustic waves parametrically amplify the spin waves during a parametric interaction, and wherein the parametric interaction extends over a specific region of space and specific duration in time.

11. The system of claim 1, wherein the acoustic wave transducer is configured to parametrically amplify the spin waves in one or more spin wave circuits.

12. The system of claim 1, wherein a range of frequencies over which the system operates is adjustable by a magnetic field.

13. The system of claim 1, wherein the magnetostrictive material comprises a ferrite material.

14. The system of claim 1, wherein the acoustic wave transducer is oriented at an angle such that an idler spin wave resulting from a parametric interaction between the acoustic waves and the spin waves is a standing, non-propagating spin wave.

15. The system of claim 2, wherein a range of input frequencies for the input spin wave transducer and the acoustic wave transducer are selected so that output spin waves in a third distinct frequency range are produced in a parametric interaction between the acoustic waves and the spin waves.

16. A device, comprising:
an acoustic transducer configured to produce surface acoustic waves in a plane of a magnetostrictive material;
at least one spin wave transducer configured to produce spin waves, wherein the spin waves propagate in the plane of the magnetostrictive material and parametrically interact with the surface acoustic waves.

17. The device of claim 16, wherein the at least one spin wave transducer comprises:
an input spin wave transducer configured to generate the spin waves; and
an output spin wave transducer configured to measure output spin waves;
wherein the input spin wave transducer is positioned at an angle relative to the acoustic wave transducer, and wherein the output spin wave transducer is positioned relative to the acoustic wave transducer and the input spin wave transducer based on the angle to measure the output spin waves.

18. A method, comprising:
converting electrical signals to spin waves, wherein the spin waves propagate in a plane of a magnetostrictive material;
generating acoustic waves in the plane of the magnetostrictive material at an angle relative to the spin waves; and
converting output spin waves to output electrical signals, the output spin waves generated during a parametric interaction between the spin waves and the acoustic waves.

19. The method of claim 18, wherein the output spin waves comprise one or more of the spin waves parametrically amplified by the acoustic waves or idler spin waves generated during the parametric interaction.

20. The method of claim 19, further comprising converting the electrical signals to the spin waves with an input spin wave transducer, and converting the output spin waves to output electrical signals with an output spin wave transducer, wherein the output spin wave transducer is positioned relative to the input spin wave transducer to capture at least one of the spin waves parametrically amplified by the acoustic waves or the idler spin waves.
